(19) United States
(12) Patent Application Publication
(10) Pub. No.: US 2007/0204798 A1
(43) Pub. Date: Sep. 6, 2007

(54) Apparatus for evaporating vapor-deposition material

(75) Inventors: Akinori Iwasaki, Odawara-shi (JP); Makoto Kashiwaya, Odawara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation, Tokyo (JP)

(21) Appl. No.: 11/711,785

(22) Filed: Feb. 28, 2007

(30) Foreign Application Priority Data
Mar. 1, 2006 (JP) 2006-054701

(51) Int. Cl. C23C 16/00

(52) U.S. Cl. 118/726

(57) ABSTRACT

An apparatus for evaporating vapor-deposition material includes a vapor-deposition vessel with a depth greater than or equal to a predetermined value. The apparatus for evaporating vapor-deposition material further includes a heating means for heating the vapor-deposition material held in the vapor-deposition vessel so that the vapor-deposition material has a temperature gradient decreasing in the depth direction of the vapor-deposition vessel toward the bottom of the vessel.

### BACKGROUND OF THE INVENTION

1. Field of the Invention

The present invention relates to an apparatus for evaporating vapor-deposition material. Particularly, the present invention relates to an apparatus for evaporating vapor-deposition material that includes a vapor-deposition vessel (vapor-deposition container) for holding vapor-deposition material, the depth of the vapor-deposition vessel being greater than or equal to a predetermined value.

2. Description of the Related Art

Conventionally, a vapor-deposition apparatus for depositing coating on a substrate by evaporating vapor-deposition material in a vacuum processing chamber is widely known. Such a vapor-deposition apparatus includes an apparatus for evaporating vapor-deposition material. Further, the apparatus for evaporating vapor-deposition material includes a vapor-deposition vessel for holding vapor-deposition material and a heating means for heating the vapor-deposition material. The vapor-deposition apparatus is structured so that the vapor-deposition material is deposited on the substrate by evaporating the vapor-deposition material.

A heating means of a conventional evaporation apparatus is structured so that the vapor-deposition material is evaporated by indirectly heating the vapor-deposition material from the outer-circumferential side of the vapor-deposition vessel. Therefore, there is a problem that the temperature of the vapor-deposition material on the center-side of the vessel and that of the vapor-deposition material on the outer-circumferential side of the vessel become much different from each other. To solve such a problem in the conventional technique, an evaporation apparatus has been proposed in Japanese Unexamined Patent Publication No. 2002-348658. In the evaporation apparatus, a radiation heater is arranged above the vessel, and vapor-deposition material is directly heated by radiation heat from the surface of the vapor-deposition material. The evaporation apparatus is structured so that the temperature of the vapor-deposition material at the evaporation surface of the vapor-deposition material becomes uniform.

Meanwhile, in medical fields or the like, various kinds of radiation image detectors (solid-state detectors) have been proposed and actually used. The radiation image detectors record radiation images related to subjects by generating electric charges (charges) by irradiation with radiation transmitted through the subjects and by storing the charges. For example, as the radiation image detectors, a radiation image detector has been proposed in U.S. Pat. No. 6,770,901. In the radiation image detector, a first electrode layer, a photoconductive layer for recording, a charge transfer layer, a photoconductive layer for readout and a second electrode layer are superposed one on another in this order. The first electrode layer transmits radiation, and the photoconductive layer for recording generates charges by irradiation with the radiation. The charge transfer layer acts as an insulator for latent image charges but acts as a conductor for transfer charges that have an opposite polarity to that of the latent image charges. The photoconductive layer for readout generates charges by irradiation with readout light. In the second electrode layer, transparent linear electrodes and light-blocking linear electrodes are alternately arranged in parallel. The transparent linear electrodes linearly extend and transmit readout light. The light-blocking linear electrodes linearly extend and block the readout light.

Further, a method for producing a photoconductive layer in such a radiation image detector by vapor deposition has been disclosed, for example, in Japanese Unexamined Patent Publication No. 2000-319773. When a radiation image detector is produced, it is necessary to carry out vacuum vapor deposition on a large substrate, which is greater than or equal to approximately 17 inch, to detect radiation images. Further, it is necessary to form a layer (coating) of which the thickness is greater than or equal to a few hundreds μm to improve the sensitivity of detection.

To form a thick layer on a large substrate, as described above, it is necessary to use a vapor-deposition vessel that has a substantial depth and a large volume. When such a vapor-deposition vessel is used, the temperature of the vapor-deposition material in the vicinity of the evaporation surface thereof and the temperature of the vapor-deposition material on the inner side of the vessel become different from each other in some cases. If the temperature of melted vapor-deposition material on the inner side becomes higher than that of the melted vapor-deposition material at the surface thereof, the high temperature portion on the inner side selectively evaporates and bumping occurs. If bumping occurs, a dumpling-like mass of particles evaporates at once and attaches to the substrate, thereby forming projection-shaped defects (layer defects or coating defects) in some cases.

### SUMMARY OF THE INVENTION

In view of the foregoing circumstances, it is an object of the present invention to provide an apparatus for evaporating vapor-deposition material. The apparatus includes a vapor-deposition vessel (vapor-deposition container) with a depth greater than or equal to a predetermined value. Further, the apparatus can suppress bumping of the vapor-deposition material during heating of the vapor-deposition material.

An apparatus for evaporating vapor-deposition material of the present invention is an apparatus for evaporating vapor-deposition material, the apparatus comprising:

a vapor-deposition vessel for holding vapor-deposition material, the vessel having a depth greater than or equal to a predetermined value; and

a heating means for heating the vapor-deposition material held in the vapor-deposition vessel, wherein the heating means heats the vapor-deposition material so that the vapor-deposition material has a temperature gradient decreasing in the depth direction of the vessel toward the bottom of the vessel.

Here, the phrase “a depth greater than or equal to a predetermine value” refers to a depth greater than or equal to ½ of the shortest diameter (shortest length) of the opening of the vapor-deposition vessel or a depth greater than or equal to ½ of the length of the opening of the vapor-deposition vessel in a narrow direction. If the opening of the vapor-deposition vessel is a circle, the diameter of the opening is the shortest diameter. If the opening of the vapor-deposition vessel is an ellipse (oval), the length of the short axis of the ellipse (the short diameter of the ellipse) is the shortest diameter. If the opening is a rectangle, the length of the shorter side (width) of the rectangle is the length of the opening in the narrow direction. Further, the depth is a length from the opening of the vessel to the bottom of the vessel. If the bottom of the vessel is not flat, the depth is a length from the opening of the vessel to the deepest part of the vessel.

The heating means may include a plurality of heaters arranged on the outer circumference of the vapor-deposition vessel. Further, the plurality of heaters may be arranged at different positions from each other with respect to the depth direction of the vessel. When the vapor-deposition material is heated, the temperature of a heater arranged on the upper side of the vapor-deposition material may be set at a higher temperature than that of a heater arranged on the bottom side of the vessel.

The heating means may include a heater arranged above the vapor-deposition material and the heater may heat the vapor-deposition material from a position above the vapor-deposition material.

Alternatively, the heating means may include a resistance-heat-generation-type heater that is arranged on the outer circumference of the vapor-deposition vessel and that extends from a side corresponding to the highest portion of the vapor-deposition material toward the bottom side of the vessel. Further, a lead wire for transmitting electric current to the heater may be arranged in the vicinity of the position corresponding to the highest portion of the vapor-deposition material.

Further, the heating means may include a coil-shaped heater wound around the outer circumference of the vapor-deposition vessel. Further, the heater may be wound around the outer circumference of the vapor-deposition vessel so that the density of the numbers of turns of winding gradually decreases in the depth direction of the vapor-deposition vessel toward the bottom side of the vapor-deposition vessel.

In the apparatus for evaporating vapor-deposition material of the present invention, the heating means heats vapor-deposition material so that the vapor-deposition material has a temperature gradient decreasing in the depth direction of the vessel toward the bottom of the vessel. Therefore, the temperature of melted vapor-deposition material on the surface side becomes higher than that of the melted vapor-deposition material on the inner side, and evaporation at the surface of the melted vapor-deposition material is accelerated. Hence, it is possible to suppress evaporation from the inner portion of the melted vapor-deposition material, thereby preventing bumping.

Further, the heating means may include a plurality of heaters arranged on the outer circumference of the vapor-deposition vessel, and the plurality of heaters may be arranged at different positions from each other with respect to the depth direction of the vessel. Further, when the vapor-deposition material is heated, the temperature of a heater arranged on the upper side of the vapor-deposition material may be set at a higher temperature than that of a heater arranged on the bottom side of the vessel. Use of such a heating means allows the vapor-deposition material to have a temperature gradient decreasing in the depth direction of the vessel toward the bottom of the vessel in a simple accurate manner.

Further, the heating means may include a heater arranged above the vapor-deposition material, and the heater may heat the vapor-deposition material from a position above the vapor-deposition material (the surface side of the vapor-deposition material). If such a heating means is used, it is possible to keep the temperature of the vapor-deposition material at the surface of the vapor-deposition material at a higher level than that of the vapor-deposition material on the inner side of the vessel and the bottom side of the vessel.

The heating means may include a resistance-heat-generation-type heater that is arranged on the outer circumference of the vapor-deposition vessel and that extends from a side corresponding to the highest portion of the vapor-deposition material toward the bottom side of the vessel. Further, a lead wire for transmitting electric current to the heater may be arranged in the vicinity of the position corresponding to the highest portion of the vapor-deposition material. If such a heating means is used, when electricity is transmitted, the density of electric current at a portion of the heater corresponding to the highest portion of the vapor-deposition material becomes greater than that of electric current at a portion of the heater corresponding to the bottom side of the vessel. Therefore, it becomes possible that the vapor-deposition material has a temperature gradient decreasing in the depth direction of the vessel toward the bottom of the vessel in a simple structure.

The heating means may include a coil-shaped heater wound around the outer circumference of the vapor-deposition vessel. Further, the heater may be wound around the outer circumference of the vapor-deposition vessel so that the density of the numbers of turns of winding gradually decreases in the depth direction of the vapor-deposition vessel toward the bottom side of the vapor-deposition vessel. If such a heating means is used, since the heat generation amount (heating value) increases as the density of the numbers of turns increases, the heat generation amount decreases in the depth direction of the vessel toward the bottom side of the vessel. Hence, it becomes possible that the vapor-deposition material has a temperature gradient decreasing in the depth direction toward the bottom of the vessel in an accurate manner.

### BRIEF DESCRIPTION OF THE DRAWINGS

FIG. 1 is a schematic diagram illustrating the structure of a vapor-deposition apparatus including an apparatus for evaporating vapor-deposition material according to the first embodiment of the present invention;

FIG. 2A is a perspective view illustrating a major part of the apparatus for evaporating vapor-deposition material according to the first embodiment of the present invention;

FIG. 2B is a cross-sectional view illustrating the major part of the apparatus for evaporating the vapor-deposition material according to the first embodiment of the present invention;

FIG. 3A is a perspective view illustrating a major part of an apparatus for evaporating vapor-deposition material according to a second embodiment of the present invention;

FIG. 3B is a cross-sectional view illustrating the major part of the apparatus for evaporating the vapor-deposition material according to the second embodiment of the present invention;

FIG. 4A is a perspective view illustrating a major part of an apparatus for evaporating vapor-deposition material according to a third embodiment of the present invention;

FIG. 4B is a cross-sectional view illustrating the major part of the apparatus for evaporating the vapor-deposition material according to the third embodiment of the present invention;

FIG. 5A is a perspective view illustrating a major part of an apparatus for evaporating vapor-deposition material according to a fourth embodiment of the present invention;

FIG. 5B is a cross-sectional view illustrating a major part of the apparatus for evaporating vapor-deposition material according to the fourth embodiment of the present invention;

FIG. 6 is a cross-sectional view of a major part of an apparatus for evaporating vapor-deposition material in a comparative example; and

FIG. 7 is a diagram illustrating the structure of a solid-state detector.

### DESCRIPTION OF THE PREFERRED EMBODIMENTS

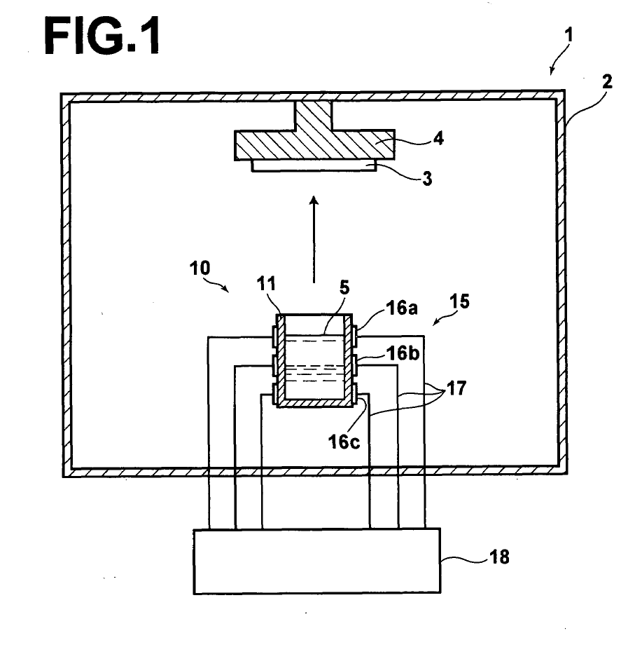

Hereinafter, embodiments of the present invention will be described with reference to the attached drawings. FIG. 1 is a schematic diagram illustrating the structure of a vapor-deposition apparatus 1. The vapor-deposition apparatus 1 forms a coating on a substrate (base plate) by depositing vapor-deposition material on the substrate by evaporating the vapor-deposition material by heating.

The vapor-deposition apparatus 1 includes a processing chamber 2, a substrate holder 4 for holding a substrate 3 and an apparatus 10 for evaporating vapor-deposition material according to the first embodiment of the present invention. The substrate holder 4 is provided on the upper inner surface of the processing chamber 2.

The apparatus 10 for evaporating vapor-deposition material according to the present embodiment includes a vapor-deposition vessel (vapor-deposition container) 11 for holding or keeping vapor-deposition material 5 and a heating means 15 for heating the vapor-deposition vessel 11. The heating means 15 is a means for evaporating the vapor-deposition material by melting and heating the vapor-deposition material by indirectly heating the vapor-deposition material. The heating means 15 heats the vapor-deposition vessel 11 from the outside of the vapor-deposition vessel 11. Here, the heating means 15 includes three outer-circumference heaters 16a, 16b and 16c and a temperature control unit 18 including a power source connected to the three heaters 16a, 16b and 16c through lead wires 17 (17a, 17b and 17c). The three outer-circumference heaters 16a, 16b and 16c are provided on the outer circumference of the vapor-deposition vessel 11. The temperature control unit 18 controls the set temperature of each of the heaters. Please note that support members of the vapor-deposition vessel, heaters and the like are omitted in FIG. 1.

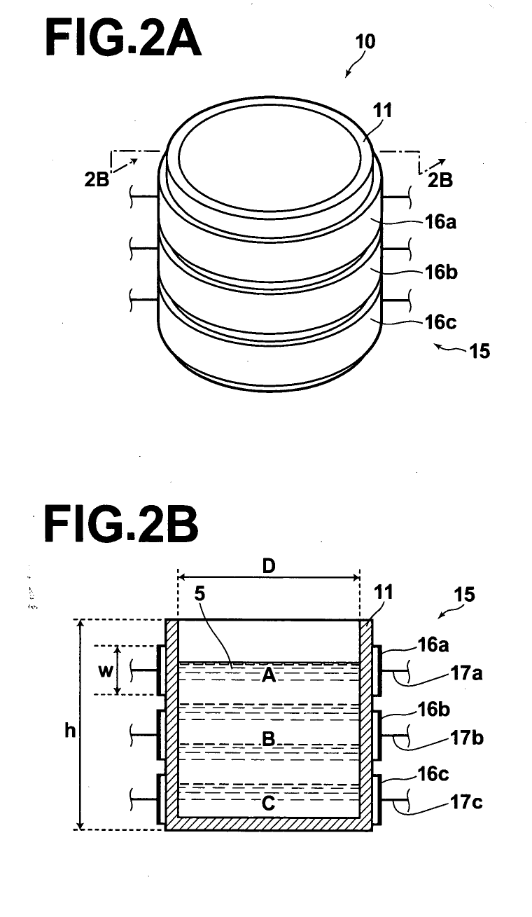

FIGS. 2A and 2B are diagrams illustrating the vapor-deposition vessel 11 and the heaters 16a, 16b and 16c of the apparatus 10 for evaporating vapor-deposition material in detail. FIG. 2A is a perspective view and FIG. 2B is a cross-sectional view at 2B-2B in FIG. 2A. The vapor-deposition vessel 11 has a cylindrical shape. The diameter of the vessel is D and the depth of the vessel is h. The present invention is directed to an evaporation apparatus including a vapor-deposition vessel in which the relationship between the shortest diameter (the diameter of a circle in this case) D and the depth h satisfies h≧D/2. The vapor-deposition vessel 11 in the present embodiment has diameter D and depth h that satisfy h≧D/2.

Further, each of the heaters 16a, 16b and 16c is produced by forming a tantalum plate into a cylindrical shape. The heaters 16a, 16b and 16c are arranged at positions different from each other with respect to the depth direction of the vessel, namely, the heater 16a at the highest position among the three, the heater 16b at the center and the heater 16c at a lower position. The temperature control unit 18 controls the set temperatures Ta, Tb and Tc of the respective heaters 16a, 16b and 16c so that the values of Ta, Tb and Tc satisfy the relationship of Ta>Tb>Tc. Accordingly, the temperature control unit 18 controls temperatures T_{A}, T_{B} and T_{C} of the vapor-deposition material 5 so that the values of T_{A}, T_{B} and T_{C} satisfy T_{A}>T_{B}>T_{C}. The temperature T_{A} is a temperature in the vicinity A of the surface of the melted vapor-deposition material 5. The temperature T_{B} is a temperature in the vicinity B of the center of the vapor-deposition material 5 with respect to the depth. The temperature T_{C} is a temperature in the vicinity C of the bottom of the vapor-deposition material 5.

The operation of the vapor-deposition apparatus 1 will be described. The vapor-deposition vessel 11 that holds the vapor-deposition material 5 is set in the processing chamber 2. While the processing chamber 2 is kept in a vacuum state, the vapor-deposition vessel 11 is heated by the heaters 16a, 16b and 16c. Accordingly, the vapor-deposition material 5 in the vapor-deposition vessel 11 is heated. Then, the vapor-deposition material 5 melts and evaporates. The evaporated vapor-deposition material 5 reaches the substrate 3 and deposited on the substrate 3 to form a coating. In actual structures, a shutter (not illustrated) is provided between the vapor-deposition vessel 11 and the substrate 3. The shutter is kept closed at the early stage of heating. When heating continues and the state of the vapor-deposition material 5 becomes a constant state, the shutter is opened to perform vapor-deposition.

First, the vessel holds the vapor-deposition material so that the surface of the melted vapor-deposition material is positioned approximately at 80% of the depth of the vessel from the bottom of the vessel. The position approximately at 80% of the depth of the vessel from the bottom of the vessel substantially corresponds to the position at which the upper heater 16a is arranged. However, when vapor-deposition continues, the surface of the melted vapor-deposition material gradually becomes lower. If the surface becomes lower, the set temperature of the central heater 16b and the lower heater 16c should be controlled so that the temperature of the vapor-deposition material becomes different according to the positions of the vapor-deposition material. To achieve the major purpose of the present invention, it is sufficient if the number of the heaters is at least two. However, it is more desirable that the number of the heaters is at least three so as to cope with cases in which the surface of the melted vapor-deposition material becomes gradually lower.

In the above embodiment, a case in which three cylindrical heaters are provided as a heating means has been described. However, the material, the number and the shapes of the heaters are not limited to those described above. For example, a plurality of lamp heaters may be provided at different positions with respect to the depth direction of the vessel. Further, although the plurality of heaters that are made of the same material and that have the same shape is provided in the aforementioned example, a plurality of heaters that are made of different materials from each other and/or that have different shapes from each other may be provided. For example, heaters made of materials of which the resistance values are different from each other may be provided, and the heating means may be structured so as to utilize the difference in the heat generation amounts based on the difference in the resistance values.

Next, another embodiment of the apparatus for evaporating vapor-deposition material provided in the aforementioned vapor-deposition apparatus 1 will be described.

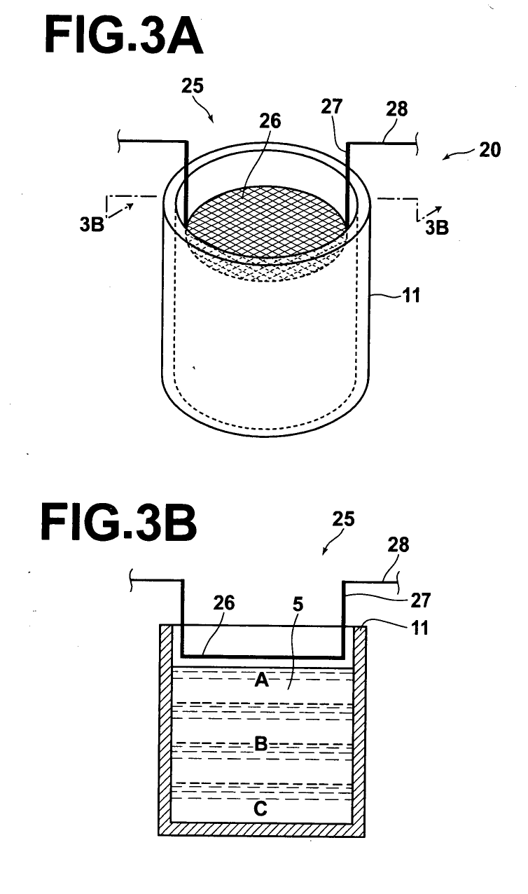

FIGS. 3A and 3B are schematic diagrams illustrating the structure of the major part of the apparatus for evaporating vapor-deposit material in the second embodiment of the present invention. FIG. 3A is a perspective view and FIG. 3B is a cross-sectional view at 3B-3B in FIG. 3A.

An apparatus 20 for evaporating vapor-deposition material in the present embodiment includes a vapor-deposition vessel 11 for holding the vapor-deposition material and a heating means 25 for heating the vapor-deposition vessel 11. The heating means 25 includes a heater 26, a support member 27 made of metal and a power source (not illustrated). The heater 26 is arranged above the vapor-deposition material 5 that is held in the vapor-deposition vessel 11. The heater 26 evaporates the vapor-deposition material by melting and heating the vapor-deposition material. The support member 27 supports the heater 26 so that the heater 26 is positioned above the vapor-deposition material. The power source is connected to the heater 26 through the support member 27 and a lead wire 28. The vapor-deposition vessel 11 used in the second embodiment is similar to the one used in the first embodiment. Therefore, detailed description of the vapor-deposition vessel will be omitted.

The heater 26 is disk-shaped, and the diameter of the heater 26 is slightly smaller than diameter D of the vapor-deposition vessel 11. The heater 26 includes a mesh member made of tantalum. The size of the mesh of the mesh member may be approximately 10 μm through 500 μm, for example. The heater 26 is positioned above the highest portion of the vapor-deposition material 5 (the surface of the melted vapor-deposition material) in close proximity thereto, and the heater 26 heats the vapor-deposition material 5 from a position above the vapor-deposition material 5. Accordingly, it is possible to heat the vapor-deposition material 5 so that temperatures T_{A}, T_{B} and T_{C} of the vapor-deposition material 5 satisfy T_{A}>T_{B}>T_{C}. The temperature T_{A} is a temperature in the vicinity A of the surface of the melted vapor-deposition material 5. The temperature T_{B} is a temperature in the vicinity B of the center of the vapor-deposition material 5 with respect to the depth. The temperature T_{C} is a temperature in the vicinity C of the bottom of the vapor-deposition material 5.

If vapor-deposition continues and the surface of the melted vapor-deposition material 5 becomes lower, the position of the heater 26 should be moved closer to the surface of the melted vapor-deposition material 5. Alternatively, the temperature may be adjusted by increasing the output of the heater. The vapor-deposition material 5 passes through the mesh of the heater 26 and reaches the substrate 3. Accordingly, vapor-deposition is performed.

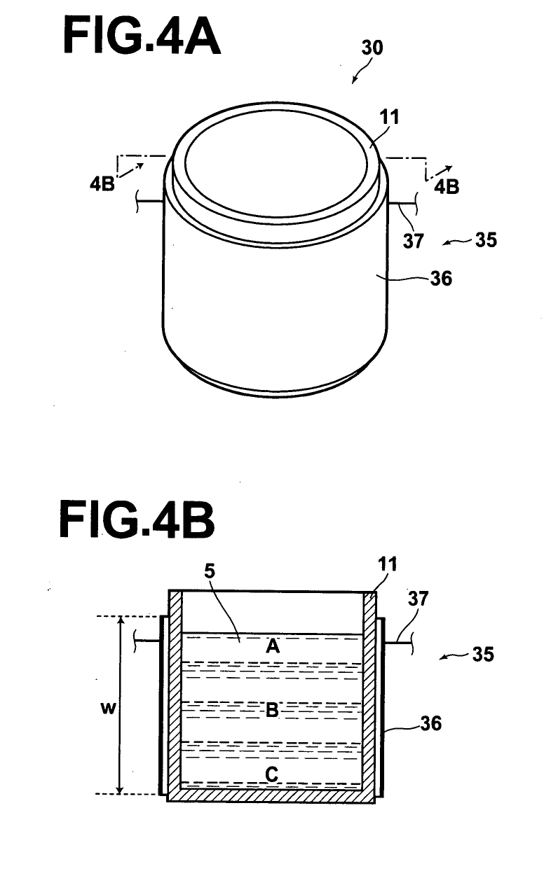

FIGS. 4A and 4B are schematic diagrams illustrating the structure of the major part of the apparatus for evaporating vapor-deposit material in the third embodiment of the present invention. FIG. 4A is a perspective view and FIG. 4B is a cross-sectional view at 4B-4B in FIG. 4A.

An apparatus 30 for evaporating vapor-deposition material according to the present embodiment includes a vapor-deposition vessel 11 for holding vapor-deposition material 5 and a heating means 35 for heating the vapor-deposition vessel 11. The heating means 35 is a means for evaporating the vapor-deposition material by melting and heating the vapor-deposition material by indirectly heating the vapor-deposition material. The heating means 35 heats the vapor-deposition vessel 11 from the outside of the vapor-deposition vessel 11. Here, the heating means 35 includes a resistance-heat-generation-type heater 36 and a power source (not illustrated). The resistance-heat-generation-type heater 36 is arranged on the outer circumference of the vapor-deposition vessel. The resistance-heat-generation-type heater 36 extends from a side corresponding to the highest portion of the vapor-deposition material to the bottom side of the vessel. The power source is connected to the heater 36 through a lead wire 37. The lead wire 37 for transmitting electric current to the heater 36 is arranged in the vicinity of a position of the heater 36, the position corresponding to the highest portion of the vapor-deposition material. When electricity is transmitted, the density of electric current at a portion of the heater 36, the portion connected to the lead wire 37, becomes higher than that of electric current at a portion of the heater 36 corresponding to the bottom side of the vessel. Here, the portion of the heater 36 connected the lead wire 37 is a portion corresponding to the highest portion of the vapor-deposition material. Therefore, it is possible to heat the vapor-deposition material 5 so that temperatures T_{A}, T_{B} and T_{C} of the vapor-deposition material 5 satisfy T_{A}>T_{B}>T_{C}. The temperature T_{A} is a temperature in the vicinity A of the surface of the melted vapor-deposition material 5. The temperature T_{B} is a temperature in the vicinity B of the center of the vapor-deposition material 5 with respect to the depth. The temperature T_{C} is a temperature in the vicinity C of the bottom of the vapor-deposition material 5.

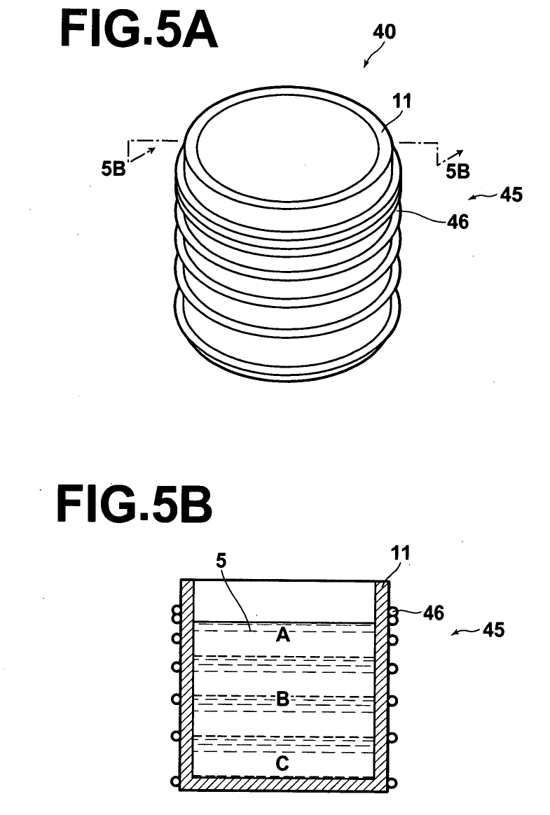

FIGS. 5A and 5B are schematic diagrams illustrating the structure of the major part of the apparatus for evaporating vapor-deposit material in the fourth embodiment of the present invention. FIG. 5A is a perspective view and FIG. 5B is a cross-sectional view at 5B-5B in FIG. 5A.

An apparatus 40 for evaporating vapor-deposition material according to the present embodiment includes a vapor-deposition vessel 11 for holding vapor-deposition material 5 and a heating means 45 for heating the vapor-deposition vessel 11. The heating means 45 is a means for evaporating the vapor-deposition material by melting and heating the vapor-deposition material by indirectly heating the vapor-deposition material. The heating means 45 heats the vapor-deposition vessel 11 from the outside of the vapor-deposition vessel 11. Here, the heating means 45 includes a coil-shaped heater 46 and a power source (not illustrated) connected to the heater 46. The coil-shaped heater 46 is wound around the outer circumference of the vapor-deposition vessel 11 so that the density of the numbers of turns of winding gradually decreases in the depth direction of the vessel toward the bottom of the vessel. The coil-shaped heater 46 is wounded around the vessel so that the density of the numbers of turns of winding gradually becomes lower from the upper side of the vessel toward the bottom side of the vessel. In the coil-shaped heater, if the density of the numbers of turns of winding is higher, the heat generation amount thereof is higher. Therefore, when electricity is transmitted, the heat generation amount becomes lower toward the bottom side of the vessel, in which the density is lower. Hence, it is possible to heat the vapor-deposition material 5 so that temperatures T_{A}, T_{B} and T_{C} of the vapor-deposition material 5 satisfy T_{A}>T_{B}>T_{C}. The temperature T_{A} is a temperature in the vicinity A of the surface of the melted vapor-deposition material 5. The temperature T_{B} is a temperature in the vicinity B of the center of the vapor-deposition material 5 with respect to the depth. The temperature T_{C} is a temperature in the vicinity C of the bottom of the vapor-deposition material 5.

We have conducted experiments on the apparatus for evaporating vapor-deposition material in each of the aforementioned embodiments of the present invention to compare them with a conventional apparatus. The result of the experiments will be described.

The material of the vapor-deposition vessels used in all of the experiments is a compound (hereinafter, referred to as “SBN”) of boron nitride (BN) and silicon nitride (Si₃N₄). The ratio of BN to SiN in the compound is 70% to 30%.

As the vapor-deposition vessel 11, a vapor-deposition vessel that has an inner diameter of 70 mm, the thickness of the vessel of 5 mm and depth h of 75 mm is used. Vapor-deposition material is put in the vessel so that the surface of the melted vapor-deposition material is positioned approximately at 60 mm from the bottom of the vessel when the vapor-deposition material is melted.

Example 1 is an example of the evaporation apparatus 20 in the first embodiment. In Example 1, a cylindrical heater with a diameter of 84 mm and with a width W of 20 mm is used as each of the heaters 16a, 16b and 16c. Each of the cylindrical heaters is formed from a thin tantalum plate with a thickness of 0.2 mm.

Example 2 is an example of the evaporation apparatus 30 in the second embodiment. In Example 2, a disk-shaped heater with a diameter of 65 mm is used as the heater 26. Mesh-shaped tantalum is used to form the disk-shaped heater, and the size of the mesh of the mesh-shaped tantalum is 200 μm.

Example 3 is an example of the evaporation apparatus 40 in the third embodiment. In Example 3, a cylindrical heater with a diameter of 84 mm and with a width W of 60 mm is used as the heater 36. The cylindrical heater is formed from a thin tantalum plate with a thickness of 0.2 mm.

Example 4 is an example of the evaporation apparatus 50 in the fourth embodiment. In Example 4, a heater formed by winding linearly-shaped tantalum (tantalum wire) with a diameter of 5 mm is used as the heater 46.

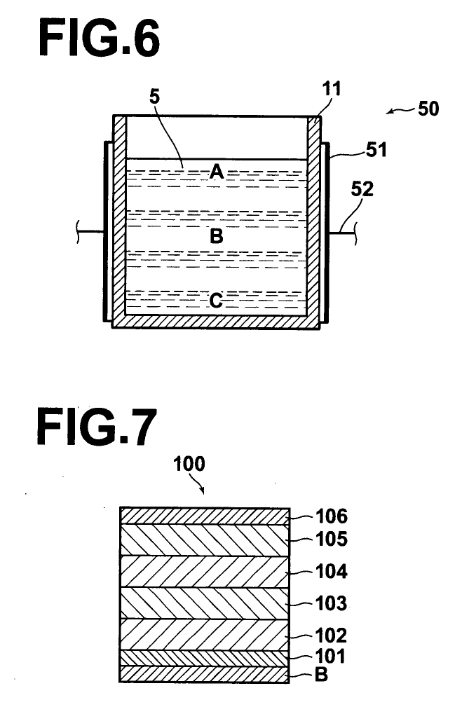

FIG. 6 is a cross-sectional view of an evaporation apparatus in a comparative example. The evaporation apparatus in the comparative example is a conventional apparatus. In the conventional apparatus, the vapor-deposition material does not have an intentionally-induced temperature gradient increasing toward the surface side of the melted vapor-deposition material. In the comparative example, a heating means is a resistance-heat-generation-type heater similar to the heater of Example 3. The resistance-heat-generation-type heater is arranged on the outer circumference of the vapor-deposition vessel 11. Further, the resistance-heat-generation-type heater extends from a side corresponding to the highest portion of the vapor-deposition material toward the bottom-side of the vessel. In the comparative example, a cylindrical heater with a diameter of 84 mm and with a width W of 60 mm is used, and the cylindrical heater is formed from a thin tantalum plate with a thickness of 0.2 mm. Unlike Example 3, in the comparative example, a lead wire 52 is connected to the center portion of the cylindrical heater with respect to the width direction of the cylindrical heater (the direction corresponding to the depth direction of the vessel).

In the evaporation apparatus of each of the examples and the comparative example, the vapor-deposition material 5 is put in the vessel 11, and the vapor-deposition material 5 is heated by a heater. Accordingly, the vapor-deposition material 5 melts and evaporates. As the vapor-deposition material 5, CsBr is used, and the vapor-deposition material 5 is deposited on a substrate with a size of 200 mm×200 mm so that the thickness of the deposited vapor-deposition material becomes 700 μm. While vapor deposition is carried out in such a manner, in Examples 1 through 4, the temperature of the vapor-deposition material 5 is controlled so that the temperature becomes approximately 680° C. in the vicinity A of the surface of the melted vapor-deposition material 5. Particularly, in Example 1, set temperatures Ta, Tb and Tc of the heaters 16a, 16b and 16c are controlled so as to satisfy Ta>Tb>Tc. Meanwhile, in the comparative example, the temperature of the heater is controlled so that temperature T_{B} in the vicinity B of the center portion becomes 670° C., which is similar to temperature T_{B} in the vicinity B of the center portion in each of Examples 1 through 4. In each of the examples 1 through 4 and the comparative example, temperature T_{A} in the vicinity A of the surface of the melted vapor-deposition material 5, temperature T_{B} in the vicinity B of the center portion of the melted vapor-deposition material 5 and temperature T_{C} in the vicinity C of the bottom of the melted vapor-deposition material 5 when the temperatures are controlled as described above are obtained. Further, the number of times of bumping per hour and the number of coating defects when the vapor-deposition material has been deposited on a substrate are obtained. Here, the number of coating defects is a number obtained by counting the number of observed defects larger than or equal to 200 μm in the CsBr coating (layer) formed on the substrate by vapor-deposition. Table 1 shows the result of the experiments.

TABLE 1

| | Temperature of | | | Number of | Number of |
|---|---|---|---|---|---|
| | Vapor-Deposition material | | | Times of | Defects |
| | in Vessel (° C.) | | | Bumping | (number of |
| | T_{A} | T_{B} | T_{C} | (times/h) | pieces) |
| Example 1 | 678 | 668 | 652 | 5 | 20 |
| Example 2 | 680 | 660 | 654 | 7 | 30 |
| Example 3 | 677 | 670 | 662 | 12 | 55 |
| Example 4 | 680 | 670 | 653 | 6 | 25 |
| Comparative | 660 | 670 | 678 | 18 | 150 |
| Example | | | | | |

As Table 1 shows, in each of Examples 1 through 4, the vapor-deposition material has a temperature gradient satisfying T_{A}>T_{B}>T_{C}. In contrast, in the comparative example, the temperature of the vapor-deposition material becomes lower toward the surface of the melted vapor-deposition material. Further, the number of times of bumping per hour in the comparative example is 18, whereas the number of times of bumping per hour in each of Examples 1 through 4 is smaller that of the comparative example. The numbers of times of bumping per hour in Examples 1 through 4 are 5, 7, 12 and 6, respectively. Further, the number of defects in each of Examples 1 through 4 is much lower than that of defects in the comparative example. Specifically, the result clearly shows that the number of times of bumping is suppressed by inducing a temperature gradient decreasing from the surface of the melted vapor-deposition material toward the bottom side thereof. The temperature gradient is a temperature gradient with a highest temperature on the surface side of the vapor-deposition material. Accordingly, it is possible to considerably reduce the number of defects in the coating formed by vapor-deposition.

Next, an embodiment in which a vapor-deposition apparatus including the apparatus for evaporating vapor-deposition material of the present invention is used in production of solid-state detectors will be described. The solid-state detectors are used in radiographic apparatuses or the like. For example, the solid-state detector includes an electrostatic recording unit, which includes a photoconductive layer. The photoconductive layer exhibits conductivity by irradiation with recording light. The solid-state detector records image information by irradiation with recording light that carries image information and outputs an image signal representing the recorded image information.

FIG. 7 is a diagram illustrating an example of the structure of the solid-state detector. In a solid-state detector 100, illustrated in FIG. 7, a first electrode 101, an interface crystallization inhibition layer 102, a photoconductive layer 103 for readout, a charge transfer layer 104, a photoconductive layer 105 for recording and a second electrode 106 are superposed in this order on light-transmissive substrate B, made of glass or the like.

The first electrode 101 has a comb-shaped electrode structure. The first electrode 101 is made of ITO (Indium Tin Oxide) or IZO (Indium Zinc Oxide), for example. The interface crystallization inhibition layer 102 is made of a Se—As-based alloy. The photoconductive layer 103 for readout is made of Se. The photoconductive layer 103 for readout exhibits conductivity by irradiation with readout light and generates dipoles (pairs of charges). The charge transfer layer 104 has a function of substantially acting as an insulator for negative charges and substantially acting as a conductor for positive charges, for example. The charge transfer layer 104 is made of a Se—As-based alloy. The photoconductive layer 105 for recording exhibits conductivity by irradiation with electromagnetic wave (light or radiation) for recording and generates dipoles (pairs of charges). The photoconductive layer 105 is made of Se. The second electrode 106 is made of Au. The first electrode 101 and the second electrode 106 are electrically connected to a signal processing unit (not illustrated) for processing signals.

When the solid-state detectors, as described above, containing a Se—As-based alloy and Se as materials are produced, a plurality of kinds of apparatuses for evaporating vapor-deposition material is prepared in a processing chamber of a vapor-deposition apparatus. The apparatuses for evaporating vapor-deposition material, such as an apparatus for evaporating a Se—As-based alloy and an apparatus for evaporating Se, is prepared for the respective layers to be formed. For each of the layers to be formed, the material is heated by the evaporation apparatus and vapor-deposition is performed. As the evaporation apparatuses, the apparatuses for evaporating vapor-deposition material in Embodiment 1 through 4 may be used, for example.

More specifically, the first electrode 101 is formed on substrate B. Further, a Se—As-based alloy is deposited on the first electrode 101 by vapor-deposition to form the interface crystallization inhibition layer 102. Further, Se is deposited on the interface crystallization inhibition layer 102 by vapor-deposition to form the photoconductive layer 103 for readout. Further, a Se—As-based alloy is deposited on the photoconductive layer 103 for readout by vapor-deposition to form the charge transfer layer 104. Further, Se is deposited on the charge transfer layer 104 by vapor-deposition to form the photoconductive layer 105 for recording. Then, the second electrode 106 is formed on the photoconductive layer 105 for recording. It is needless to say that the present invention may be applied to production of solid-state detectors other than the solid-state detector of the aforementioned example as long as the solid-state detectors are solid-state detectors in which layers can be formed by vapor-deposition.

So far, the embodiments of the present invention have been descried. However, the present invention is not limited to the aforementioned embodiments, and various modifications are possible without deviating from the major purpose of the present invention. For example, in each of the embodiments, tantalum was used as an example of the material of the heater. However, the material of the heater is not limited to tantalum, and various kinds of high-melting-point metal material may be adopted as the material of the heater. Further, the shape of the vapor-deposition vessel is not limited to a cylinder, and various modifications are possible without deviating from the major purpose of the present invention. Specifically, it is not necessary that the shape of the vapor-deposition vessel is a cylinder. The shape of the vapor-deposition vessel may be any shape as long as the depth of the vapor-deposition vessel is greater than or equal to ½ of the shortest diameter of the opening of the vapor-deposition vessel or greater than or equal to ½ of the length of the opening of the vapor-deposition vessel in a narrow direction. Further, it is not necessary that the material of the vapor-deposition vessel is SBN. The material of the vapor-deposition vessel may be various kinds of ceramics, such as alumina, carbon or metal, such as titanium and stainless steel.

What is claimed is:

1. An apparatus for evaporating vapor-deposition material, the apparatus comprising:
a vapor-deposition vessel for holding vapor-deposition material, the vessel having a depth greater than or equal to a predetermined value; and
a heating means for heating the vapor-deposition material held in the vapor-deposition vessel, wherein the heating means heats the vapor-deposition material so that the vapor-deposition material has a temperature gradient decreasing in the depth direction of the vessel toward the bottom of the vessel.

2. An apparatus for evaporating vapor-deposition material, as defined in claim 1, wherein the heating means includes a plurality of heaters arranged on the outer circumference of the vapor-deposition vessel, and wherein the plurality of heaters is arranged at different positions from each other with respect to the depth direction of the vessel, and wherein when the vapor-deposition material is heated, the temperature of a heater arranged on the upper side of the vapor-deposition material is set at a higher temperature than that of a heater arranged on the bottom side of the vessel.

3. An apparatus for evaporating vapor-deposition material, as defined in claim 1, wherein the heating means includes a heater arranged above the vapor-deposition material, and wherein the heater heats the vapor-deposition material from a position above the vapor-deposition material.

4. An apparatus for evaporating vapor-deposition material, as defined in claim 1, wherein the heating means includes a resistance-heat-generation-type heater that is arranged on the outer circumference of the vapor-deposition vessel and that extends from a side corresponding to the highest portion of the vapor-deposition material toward the bottom side of the vessel, and wherein a lead wire for transmitting electric current to the heater is arranged in the vicinity of the position corresponding to the highest portion of the vapor-deposition material.

5. An apparatus for evaporating vapor-deposition material, as defined in claim 1, wherein the heating means includes a coil-shaped heater wound around the outer circumference of the vapor-deposition vessel, and wherein the heater is wound around the outer circumference of the vapor-deposition vessel so that the density of the numbers of turns of winding gradually decreases in the depth direction of the vapor-deposition vessel toward the bottom side of the vapor-deposition vessel.
